(19) United States
(12) Patent Application Publication
(10) Pub. No.: US 2018/0245216 A1
(43) Pub. Date: Aug. 30, 2018

(54) FILM FORMING APPARATUS

(71) Applicant: TOKYO ELECTRON LIMITED, Tokyo (JP)

(72) Inventors: Jun OGAWA, Nirasaki City (JP); Noriaki FUKIAGE, Nirasaki City (JP); Shimon OTSUKI, Oshu City (JP); Muneyuki OTANI, Nirasaki City (JP); Takayuki KARAKAWA, Nirasaki City (JP); Takeshi OYAMA, Nirasaki City (JP); Masahide IWASAKI, Nirasaki City (JP)

(21) Appl. No.: 15/899,672

(22) Filed: Feb. 20, 2018

(30) Foreign Application Priority Data
Feb. 28, 2017 (JP) 2017-037325
May 10, 2017 (JP) 2017-093978

(51) Int. Cl. C23C 16/458; C23C 16/455; C23C 16/46; H01L 21/02; H01L 21/683; C23C 16/34

(52) U.S. Cl. CPC C23C 16/4584; C23C 16/45551; C23C 16/45538; C23C 16/345; H01L 21/0228; C23C 16/45557; H01L 21/6835; C23C 16/46

(57) ABSTRACT

A film forming apparatus for carrying out a film forming process on a substrate by performing a cycle of sequentially supplying a first processing gas and a second processing gas a plurality of times in a vacuum container, includes: a rotary table having one surface on which a substrate mounting region for mounting a substrate is formed; a first gas supply part including a gas discharge portion having gas discharge holes of a first gas with a uniform hole diameter, an exhaust port surrounding the gas discharge portion, and a purge gas discharge port surrounding the gas discharge portion, which are formed on an opposing surface opposite the rotary table; a second gas supply part configured to supply a second gas to a region spaced apart in a circumferential direction of the rotary table from the first gas supply part; and an evacuation port configured to evacuate the vacuum container.

### CROSS-REFERENCE TO RELATED APPLICATIONS

This application is based upon and claims the benefit of priority from Japanese Patent Application Nos. 2017-037325 and 2017-093978, filed on Feb. 28, 2017 and May 10, 2017, the entire contents of which are incorporated herein by reference.

### TECHNICAL FIELD

The present disclosure relates to a technique for forming a film on the surface of a substrate.

### BACKGROUND

In a semiconductor manufacturing process, there is a case where a film forming process for forming a film such as, for example, a SiN (silicon nitride) film is performed on a semiconductor wafer (hereinafter referred to as “wafer”) as a substrate. The SiN film is required to be formed so as to have uniform film thickness at respective portions of the wafer. As a film forming apparatus for forming a SiN film, a configuration has been used in which a rotary table for revolving a plurality of wafers arranged in a circumferential direction is provided in a processing container.

In such a film forming apparatus, a region for supplying a raw material gas to the region corresponding to the passing region of the revolving wafers and a region for generating plasma of a reaction gas are provided apart from each other. The rotary table is rotated while heating the wafers with a heating part provided under the rotary table, whereby the raw material gas and the reaction gas are respectively supplied to all surfaces of the wafers.

As a gas supply part for supplying a raw material gas, a gas supply part has been used that supplies a raw material gas toward a fan-shaped region on a rotary table. The gas supply part discharges the raw material gas from a number of gas discharge holes of the gas supply part opposite the rotary table and supplies the raw material gas to a wafer passing region from the center side to the outer peripheral side of the rotary table. Further, a gas exhaust port is provided so as to surround a discharge region of the raw material gas, and a purge gas discharge part is provided so as to surround the gas exhaust port. By discharging the raw material gas and the purge gas and exhausting them from the gas exhaust port, a region, to which the raw material gas is supplied and surrounded by the purge gas, is formed above the rotary table. By allowing the wafers to move across the region, the raw material gas is supplied and adsorbed on all surfaces of the wafers.

However, in such a gas supply part, the gas is consumed in the bevels formed on the wafers and the gap portions between the wafers and the recesses on which the wafers are mounted, whereby the concentration of the gas at the peripheral portions of the wafers is lowered. Therefore, there is a problem in that at the peripheral edges of the wafers, the adsorption amount of the gas becomes small and the film thickness becomes thin.

### SUMMARY

Some embodiments of the present disclosure provide a technique capable of suppressing variations in film thickness in a film forming apparatus that forms a film by supplying a gas to a substrate mounted on and revolved by a rotary table over a radial direction of the substrate.

According to one embodiment of the present disclosure, there is provided a film forming apparatus for carrying out a film forming process on a substrate by performing a cycle of sequentially supplying a first processing gas and a second processing gas a plurality of times in a vacuum container, including: a rotary table having one surface on which a substrate mounting region for mounting a substrate is formed, the rotary table configured to revolve the substrate mounting region in the vacuum container; a first gas supply part including a gas discharge portion having a plurality of gas discharge holes of a first gas with a uniform hole diameter, an exhaust port surrounding the gas discharge portion, and a purge gas discharge port surrounding the gas discharge portion, which are formed on an opposing surface opposite the rotary table; a second gas supply part configured to supply a second gas to a region spaced apart in a circumferential direction of the rotary table from the first gas supply part; and an evacuation port configured to evacuate the inside of the vacuum container, wherein the gas discharge portion includes three or more gas discharge regions divided in a radial direction of the rotary table and independently supplied with the first gas, and when a center side of the rotary table is defined as an inner side and an outer periphery side of the rotary table is defined as an outer side, in the gas discharge region positioned on a most outer side, an arrangement density DO1 of the gas discharge holes in a region opposite an outer edge portion of a passing region of the substrate is set to be larger than an arrangement density DO2 of the gas discharge holes in a region inwardly deviated from the region opposite the outer edge portion, and in the gas discharge region positioned on a most inner side, an arrangement density DI1 of the gas discharge holes in a region opposite an inner edge portion of the passing region of the substrate is set to be larger than an arrangement density DI2 of the gas discharge holes in a region outwardly deviated from the region opposite the inner edge portion.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a sectional view of a film forming apparatus according to the present disclosure.

FIG. 2 is a plan view of the film forming apparatus according to the present disclosure.

FIG. 3 is a side sectional view of a gas supply/exhaust unit.

FIG. 4 is a plan view of the lower surface side of the gas supply/exhaust unit.

FIGS. 5A and 5B are explanatory views showing a film thickness distribution of a film formed by a conventional film forming apparatus.

FIGS. 6A and 6B are explanatory views showing a film thickness distribution of a film formed by the film forming apparatus of the present disclosure.

FIG. 7 is an explanatory view showing a distribution of gas discharge holes in verification test 1-2.

FIG. 8 is an explanatory view showing a distribution of gas discharge holes in verification test 1-3.

FIG. 9 is a characteristic diagram showing a film thickness distribution in verification test 1.

FIG. 10 is a characteristic diagram showing a film thickness distribution in verification test 1.

FIG. 11 is a characteristic diagram showing a film thickness distribution in verification test 1.

FIG. 12 is a characteristic diagram showing a gas flow rate and a difference in film thickness in verification test 1.

FIG. 13 is an explanatory view showing a distribution of gas discharge holes in verification test 2-2.

FIG. 14 is an explanatory view showing a distribution of gas discharge holes in verification test 2-3.

FIG. 15 is a characteristic diagram showing a film thickness distribution in verification test 2-1.

FIG. 16 is a characteristic diagram showing a film thickness distribution in verification test 2-2.

FIG. 17 is a characteristic diagram showing a film thickness distribution in verification test 2-3.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

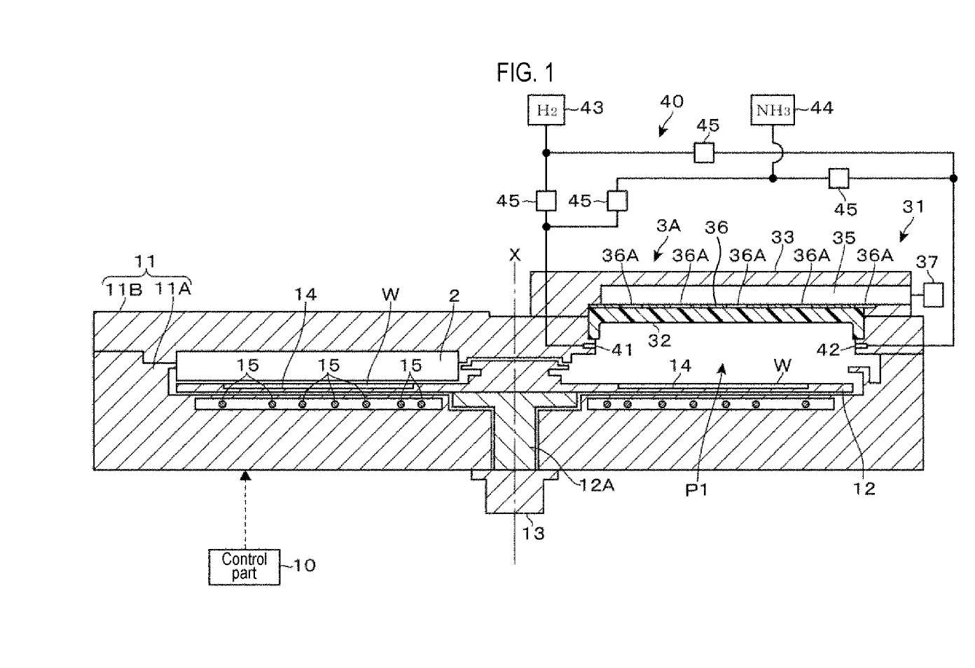

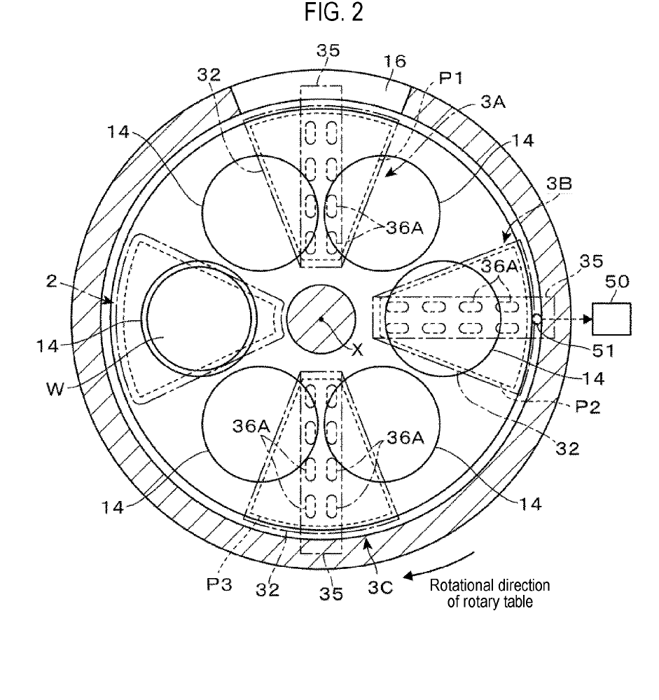

A film forming apparatus according to an embodiment of the present disclosure will be described with reference to a vertical sectional view of FIG. 1 and a plan view of FIG. 2. The film forming apparatus is configured to form a SiN film by ALD (Atomic Layer Deposition) on the surface of a semiconductor wafer (hereinafter referred to as a wafer) W which is a substrate. In the specification, regardless of the stoichiometric ratio of Si and N, silicon nitride will be described as SiN. Accordingly, the description reading SiN includes, for example, Si₃N₄.

As shown in FIG. 1, the film forming apparatus includes a flat, substantially circular vacuum container 11. The vacuum container 11 is composed of a container body 11A that constitutes a side wall and a bottom portion, and a top plate 11B. In the vacuum container 11, a circular rotary table 12 for horizontally mounting a wafer W having a diameter of 300 mm is provided. In FIG. 1, reference numeral 12A denotes a support part that supports the central portion of the rear surface of the rotary table 12. A rotation mechanism 13 is provided below the support part 12A. The rotatory table 12 rotates clockwise as viewed from above around a vertical axis via the support part 12A during a film forming process. X in FIGS. 1 and 2 denotes the rotation axis of the rotary table 12.

As shown in FIG. 2, on the upper surface of the rotary table 12, six circular recesses 14 serving as mounting portions of wafers W are provided along the circumferential direction (rotation direction) of the rotary table 12. The wafers W are accommodated in the respective recesses 14. That is, the respective wafers W are mounted on the rotary table 12 so as to be revolved by the rotation of the rotary table 12. Returning to FIG. 1, a plurality of heaters 15 is provided concentrically in the bottom portion of the vacuum container 11 below the rotary table 12, so that the wafers W mounted on the rotary table 12 are heated by the heaters 15. As shown in FIG. 2, a wafer transfer port 16 is opened in the side wall of the vacuum container 11 and is configured to be opened and closed by a gate valve (not shown). A position facing the transfer port 16 in the vacuum container 11 is a wafer transfer position. In a region corresponding to the wafer transfer position, transfer-purpose lift pins (not shown) for penetrating the recess 14 and pushing up the wafer W from the rear surface of the wafer W and a lifting mechanism (not shown) for lifting the lift pins are provided below the rotary table 12. The wafer W is transferred to the wafer transfer position via the transfer port 16 by a substrate transfer mechanism (not shown) provided outside the vacuum container 11 and is delivered to the recess 14 by the cooperative action of the substrate transfer mechanism and the lift pins.

As shown in FIG. 2, above the rotary table 12, a gas supply/exhaust unit 2 as a first gas supply part and first to third plasma formation units 3A to 3C are provided in the named order along the rotation direction of the rotary table 12, namely along the clockwise direction in this example. The first to third plasma formation units 3A to 3C correspond to a second gas supply part. An evacuation port 51 is opened below the outer side of the rotary table 12 in the vacuum container 11 and outside the second plasma formation unit 3B. The evacuation port 51 is connected to a vacuum exhaust part 50.

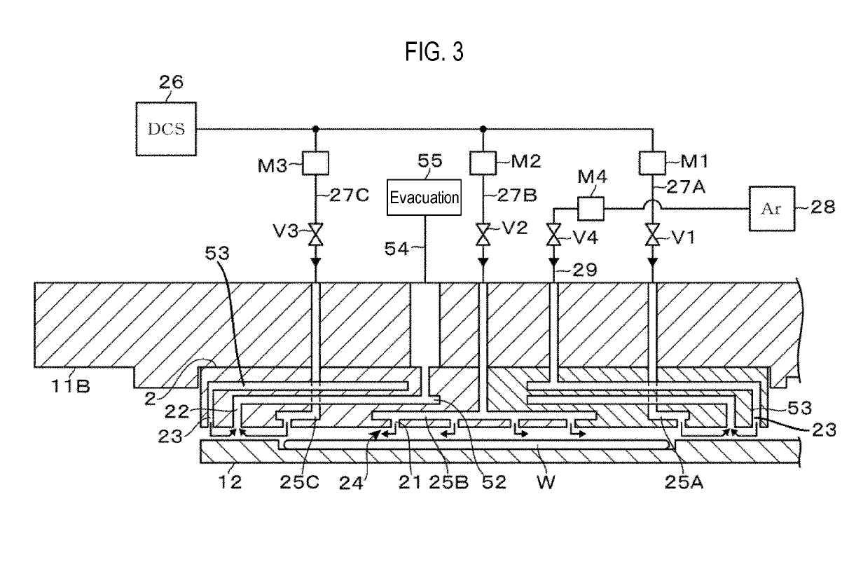

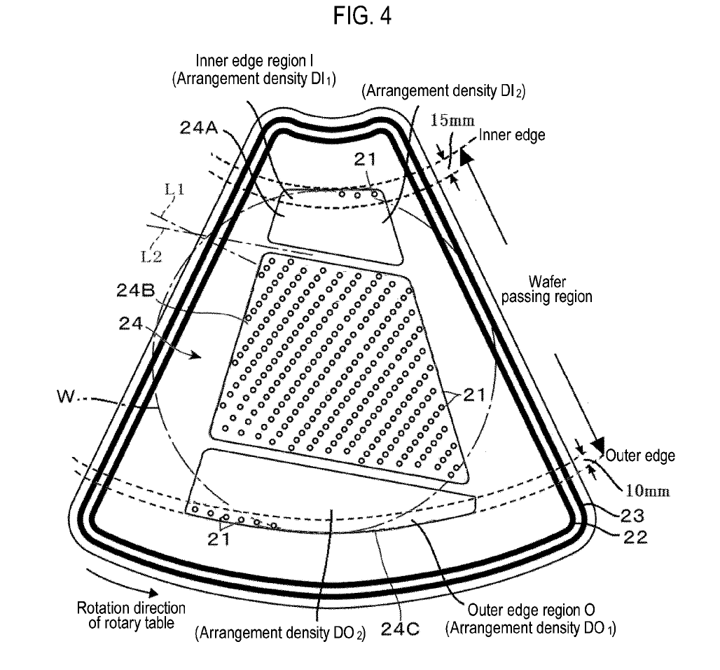

The gas supply/exhaust unit 2 will be described with reference to FIG. 3 which is a vertical sectional view and FIG. 4 which is a lower side plan view. As shown in FIG. 2, when seen in a plan view, the gas supply/exhaust unit 2 is formed in a fan-like shape widening in the circumferential direction of the rotary table 12 from the center side toward the outer periphery side of the rotary table 12. As shown in FIG. 3, the gas supply/exhaust unit 2 is disposed so that the lower surface of the gas supply/exhaust unit 2 is close to and opposite the upper surface of the rotary table 12.

Gas discharge holes 21, an exhaust port 22 and a purge gas discharge port 23 are opened on the lower surface (the opposite surface facing the rotary table) of the gas supply/exhaust unit 2. FIG. 4 schematically shows the layout and the diameter of the gas discharge holes 21 with respect to the actual gas supply/exhaust unit 2 created by the present inventor. Further, the exhaust port 22 and the purge gas discharge port 23 are respectively indicated in gray. As shown in FIG. 4, a generally fan-shaped gas discharge region 24 is formed in a region in the vicinity of the center of the lower surface of the gas supply/exhaust unit 2. The gas discharge holes 21 are dispersed in the gas discharge region 24. When the rotary table 12 is rotated, the wafer W mounted in the recess 14 is provided so as to be positioned in a region below the gas discharge region 24 as indicated by a broken line in FIG. 4.

The gas discharge region 24 is divided into an inner section 24A, a central section 24B and an outer section 24C, which are arranged from the center side of the rotary table 12 toward the outer periphery side of the rotary table 12. The respective sections are divided along a line L2. With respect to a line L1 orthogonal to the diameter of the rotary table 12 passing through the end portion of the upstream side of the gas discharge region 24 in the rotation direction of the rotary table 12, the line L2 is inclined by 10 degrees in the inner periphery direction of the rotary table 12 toward the downstream side of the rotation direction of the rotary table 12. In the specification, the center side of the rotary table 12 is defined as an inner side, and the peripheral edge side of the rotary table 12 is defined as an outer side.

The belt-like region between an inner edge of the passing region of the wafer W and a position shifted by 15 mm from the inner edge to the outer side (in the direction toward an outer edge of the rotary table 12) is defined as “an inner edge portion of the passing region of the wafer W.” In the inner section 24A closest to the center of the rotary table 12, 9 gas discharge holes 21 are provided side by side in a region (inner edge region I) opposite the inner edge portion of the passing region of the wafer W along the rotation direction of the rotary table 12. In the inner section 24A, an arrangement density of the gas discharge holes 21 in the inner edge region I is referred to as DI₁, and an arrangement density of the gas discharge holes 21 in the region outside the inner edge region I is referred to as DI₂. The arrangement density refers to the number of gas discharge holes 21 per unit area (the arrangement density=the number of gas discharge holes 21 in the region/the area of the region).

In the central section 24B adjacent to the inner section 24A, 632 gas discharge holes 21 are uniformly dispersed and arranged. A belt-like region between the outer edge of the passing region of the wafer W and the position shifted by, for example, 10 mm from the outer edge to the inner side (in the direction toward the central portion of the rotary table 12) is defined as “the outer edge portion of the passing region of the wafer W.” In the outer section 24C closest to the outer periphery of the rotary table 12, 21 gas discharge holes 21 are arranged in two rows in the region (outer edge region O) opposite the outer edge portion of the passing region of the wafer W and are disposed in the rotation direction of the rotary table 12. In the outer section 24C, an arrangement density of the gas discharge holes 21 in the outer edge region O is referred to as DO₁, and an arrangement density of the gas discharge holes 21 in the region outside the outer edge region O is referred to as DO₂.

The gas discharge holes 21 provided in each of the inner section 24A, the central section 24B and the outer section 24C have uniform hole diameters. For example, all the gas discharge holes 21 are formed such that the inner diameter on the upstream side is 0.3 mm and the hole diameter of the openings on the downstream side is 1.0 mm. The fact that the hole diameters of the gas discharge holes 21 are uniform includes the meaning that when there is a variation in the hole diameter of the opening, the hole diameter at the opening of the largest gas discharge hole 21 is, for example, 1.5 times or less of the hole diameter at the opening of the smallest gas discharge hole 21.

In this example, the interval between the respective adjacent gas discharge holes 21 in the inner edge region I, the interval between the respective adjacent gas discharge holes 21 in the outer edge region O, and the interval between the respective adjacent gas discharge holes 21 in the central section 24B are set to the same distance. In addition, the gas discharge holes 21 are arranged so that distances from the center position of the rotary table 12 to the center positions of the gas discharge holes 21 are different from one another. Accordingly, the gas discharged from the respective gas discharge holes 21 is discharged toward different positions in the radial direction of the rotary table 12 on the wafer W revolving under the gas supply/exhaust unit 2. Therefore, it is possible to prevent the gas supplied to the wafer W from concentrating on the same location. Thus, a film is uniformly formed. In FIG. 4, the arrangement of the gas discharge holes 21 in each of the inner edge region I, the outer edge region O and the central section 24B is not precisely shown in order to avoid a complicated illustration.

As shown in FIG. 3, inside the gas supply/exhaust unit 2, gas flow paths 25A, 25B and 25C partitioned from one another are formed so as to independently supply a DCS gas to the gas discharge holes 21 provided in the inner section 24A, the gas discharge holes 21 provided in the central section 24B, and the gas discharge holes 21 provided in the outer section 24C. The downstream ends of the respective gas flow paths 25A, 25B and 25C are connected to the gas discharge holes 21.

A DCS gas supply source 26 is connected to the upstream ends of the gas flow paths 25A, 25B and 25C via pipes 27A, 27B and 27C, respectively. In the respective pipes 27A, 27B and 27C, valves V1 to V3 and flow rate adjustment parts M1 to M3 are provided sequentially from the side of the gas flow paths 25A, 25B and 25C. The gas flow paths 25A, 25B and 25C, the valves V1 to V3 and the flow rate adjustment parts M1 to M3 connected to the DCS gas supply source 26 correspond to a gas supply part. Therefore, it is possible to independently adjust the discharge flow rates of the gas in the inner section 24A, the central section 24B and the outer section 24C.

Subsequently, the exhaust port 22 and the purge gas discharge port 23 will be described. As shown in FIGS. 3 and 4, the exhaust port 22 is formed in an annular shape surrounding the gas discharge region 24 and is opened toward the upper surface of the rotary table 12. The purge gas discharge port 23 is formed in an annular shape surrounding the outer side of the exhaust port 22 and is opened toward the upper surface of the rotary table 12.

The purge gas discharge port 23 forms an air flow curtain for discharging an Ar (argon) gas as a purge gas onto the rotary table 12. The Ar gas discharged from the purge gas discharge port 23 and the DCS gas discharged from the gas discharge holes 21 are exhausted by the exhaust part 55 via the exhaust port 22 provided between the gas discharge region 24 and the purge gas discharge port 23. By performing the discharge and exhaust of the purge gas in this way, the atmosphere below the gas discharge region 24 is separated from the external atmosphere. This makes it possible to limitedly supply the DCS gas below the gas discharge region 24.

As shown in FIG. 3, inside the gas supply/exhaust unit 2, an exhaust flow path 52 and a gas flow path 53 are partitioned from one another, and are partitioned from the above-described gas flow paths 25A to 25C of the raw material gas. The upstream end portion of the exhaust flow path 52 is connected to the exhaust port 22. The downstream end portion of the exhaust flow path 52 is connected to the exhaust part 55 via an exhaust pipe 54. The downstream end portion of the gas flow path 53 is connected to the purge gas discharge port 23. One end of a pipe 29 is connected to the upstream end portion of the gas flow path 53. The other end of the pipe 29 is connected to an Ar gas supply source 28. In the pipe 29, a valve V4 and a flow rate adjustment part M4 are provided sequentially from the side of the gas supply/exhaust unit 2.

Next, the plasma formation units 3A to 3C shown in FIG. 2 will be described. The plasma formation units 3A to 3C are similarly configured. The plasma formation unit 3A will be described here. The plasma formation unit 3A is formed in a generally fan shape widening from the center side to the outer periphery side of the rotary table 12. As shown in FIG. 1, the plasma formation unit 3A includes an antenna 31 for supplying microwaves. The antenna 31 includes a dielectric plate 32 and a metal waveguide 33.

The waveguide 33 is provided on the dielectric plate 32 and includes an internal space 35 extending along the radial direction of the rotary table 12. On the lower side of the waveguide 33, a slot plate 36 having a plurality of slot holes 36A is provided so as to make contact with the dielectric plate 32. A microwave generator 37 is connected to the waveguide 33 and is configured to supply microwaves of, for example, about 2.45 GHz to the waveguide 33.

Further, the plasma formation unit 3A is provided with a gas discharge hole 41 and a gas discharge hole 42 which are configured to supply a plasma formation gas to the lower surface side of the dielectric plate 32. The gas discharge hole 41 discharges the plasma formation gas from the center side of the rotary table 12 toward the outer periphery side, and the gas discharge hole 42 discharges, for example, a mixed gas of a H₂ (hydrogen) gas and an NH₃ (ammonia) gas from the outer periphery side to the center side of the rotary table 12. In FIG. 1, reference numeral 43 denotes a H₂ gas supply source, and reference numeral 44 denotes an NH₃ gas supply source. The gas discharge hole 41 and the gas discharge hole 42 are respectively connected to the H₂ gas supply source 43 and the NH₃ gas supply source 44 via a piping system 40 provided with gas supply devices 45. In the plasma formation unit 3A, the microwaves supplied to the waveguide 33 passes through the slot holes 36A of the slot plate 36, whereby the mixed gas of the NH₃ gas and the H₂ gas, which is the plasma formation gas discharged below the dielectric plate 32, is turned into plasma.

As shown in FIG. 1, the film forming apparatus is provided with a controller 10 including a computer. A program is stored in the controller 10. This program incorporates a group of steps so as to transmit control signals to the respective parts of the film forming apparatus to control the operations of the respective parts and so as to perform a film forming process to be described later. Specifically, the number of revolutions of the rotary table 12 rotated by the rotation mechanism 13, the power supply to the heaters 15, and the like are controlled by the program. The program is installed in the controller 10 from a storage medium such as a hard disk, a compact disk, a magneto-optical disk, a memory card, or the like.

The operation of the film forming apparatus according to an embodiment of the present disclosure will be described. First, six wafers W are mounted on the respective recesses 14 of the rotary table 12 by the substrate transfer mechanism, and the gate valve is closed. The wafers W mounted on the recesses 14 are heated to a predetermined temperature, for example, 400 degrees C. by the heaters 15. Next, evacuation is performed by the vacuum exhaust part 50 through the evacuation port 51. The internal pressure of the vacuum container 11 is set to, for example, 66.5 Pa (0.5 Torr) to 665 Pa (5 Torr). The rotary table 12 is rotated at 10 rpm to 30 rpm. In addition, the DCS gas is supplied to the inner section 24A at a flow rate of 70 sccm, to the central section 24B at a flow rate of 260 sccm, and to the outer section 24C at a flow rate of 950 sccm. Moreover, exhaust is started from the exhaust port 22 and a purge gas is discharged from the purge gas discharge port 23.

In the first to third plasma formation units 3A to 3C, the mixed gas of the H₂ gas and the NH₃ gas is discharged from the gas discharge hole 41 and the gas discharge hole 42 at a predetermined flow rate. As a result, the mixed gas of the H₂ gas and the NH₃ gas is supplied below the first to third plasma formation units 3A to 3C. At the same time, the microwaves are supplied from the microwave generator 37. The H₂ gas and the NH₃ gas are turned into plasma by the microwaves. Then, by rotating the rotary table 12, each wafer W is caused to sequentially pass under the gas supply/exhaust unit 2 and under the first to third plasma formation units 3A to 3C. The first and third plasma formation units 3A and 3C may be configured to supply a H₂ gas and turn the H₂ gas into plasma, and the second plasma formation unit 3B may be configured to supply an NH₃ gas and turn the NH₃ gas into plasma.

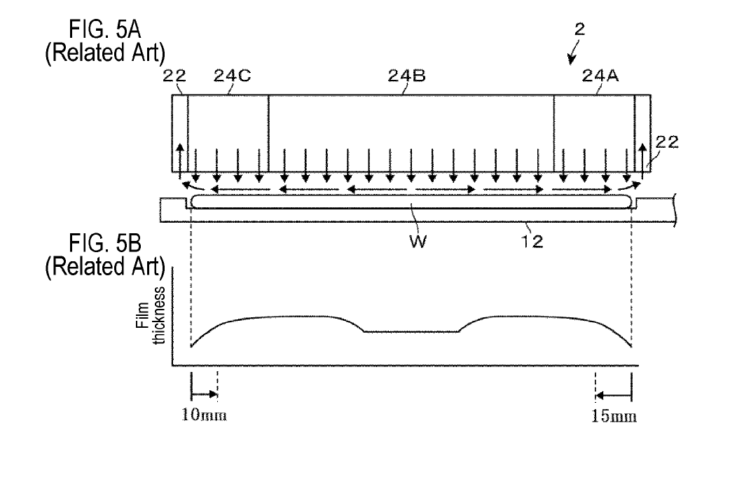

Focusing on one wafer W, the rotary table 12 rotates the wafer W and moves it to the lower side of the gas supply/exhaust unit 2. At this time, the DCS gas is supplied to the region surrounded by the gas flow of the purge gas under the gas supply/exhaust unit 2 and is adsorbed to the surface of the wafer W. In the gas supply/exhaust unit 2 shown in FIG. 4, the flow of the raw material gas in a comparative embodiment will be described prior to describing the flow of the raw material gas corresponding to the configuration of the embodiment. In the comparative embodiment, 115 gas discharge holes 21 are uniformly distributed over the entire lower surface of the inner section 24A, and 256 gas discharge holes 21 are uniformly distributed over the entire lower surface of the outer section 24C. The supply flow rate of the DCS gas in the film forming process according to the comparative embodiment is the same as the flow rate in the embodiment. The gas supply/exhaust unit 2 performs exhaust from the exhaust port 22 provided around the gas discharge region 24. As shown in FIG. 5A, on the center side and the outer periphery side of the rotary table 12, the DCS gas is supplied to the region extending from the inner side (the peripheral edge of the wafer W on the center side of the rotary table 12) to the outer side (the peripheral edge of the wafer W on the outer periphery side of the rotary table 12). The DCS gas flows from the center side of the wafer W toward the periphery side thereof. A part of the DCS gas becomes a gas flow exhausted from the exhaust port 22 through the inner peripheral edge of the wafer W or through the outer peripheral edge of the wafer W.

Therefore, in the central portion of the wafer W, the DCS gas supplied from above is adsorbed. In the region on the more peripheral edge side than the center side of the wafer W, the film thickness is increased by the DCS gas flowing from the center side of the wafer W in addition to the DCS gas supplied from above the region. On the other hand, in the vicinity of the peripheral edge of the wafer W, the amount of the DCS gas consumed is increased due to the bevel formed on the wafer W and the small gap between the wafer W and the recess 24, and the DCS gas is drawn into the exhaust port 22. Thus, the concentration of DCS gas decreases around the peripheral edge of the wafer W. Therefore, as shown in FIG. 5B, the film thickness becomes large in the region around 50 mm from the inner peripheral edge portion of the wafer W and in the region around 50 mm from the outer peripheral edge portion of the wafer W. The film thickness becomes gradually small toward the inner peripheral edge portion and the outer peripheral edge portion of the wafer W. There is a tendency that the film thickness becomes extremely small in the inner peripheral edge portion and the outer peripheral edge portion of the wafer W.

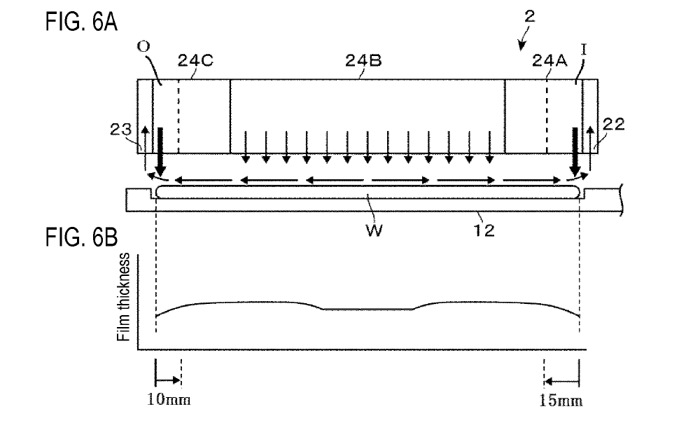

The film forming apparatus according to an embodiment of the present disclosure is configured so that, as shown in FIG. 6A, in the inner section 24A set in the gas supply/exhaust unit 2, the gas is discharged only from the inner edge region I on the center side of the rotary table 12. In addition, in the outer section 24C, the gas is discharged only from the outer edge region O on the outer periphery side of the rotary table 12. Therefore, since the gas discharge holes 21 are not provided above the region of the wafer W closer to the center of the wafer W than the peripheral edge portion of the wafer W on the inner side of the rotary table 12 and the region closer to the center of the wafer W than the peripheral edge portion of the wafer W on the outer side of the rotary table 12, the amount of the gas supplied decreases. Accordingly, as shown in FIG. 6B, it is possible to suppress an increase in film thickness in the peripheral edge portion of the wafer W on the inner side of the rotary table 12 and in the peripheral edge portion of the wafer W on the outer side of the rotary table 12. This makes it possible to improve the in-plane uniformity of the film thickness of the wafer W.

While the flow rate of the DCS gas supplied to the central section 24B is set to 260 sccm, the flow rate of the DCS gas supplied to the inner section 24A is set to 50 sccm to 100 sccm, for example, 70 sccm. The number of the gas discharge holes 21 provided in the central section 24B is 632, whereas the number of the gas discharge holes 21 in the inner section 24A is as small as 9. Therefore, the flow velocity of the gas discharged from the inner section 24A is two times or more as high as the flow velocity of the DCS gas discharged from the central section 24B. The flow rate of the DCS gas supplied from the outer section 24C is set to 900 sccm to 1000 sccm, for example, 950 sccm. Even in the outer section 24C, the number of the gas discharge holes 21 is reduced to 21. Therefore, the flow velocity of the gas discharged from the outer section 24C is two times or more as high as the flow velocity of the DCS gas discharged from the central section 24B. Thus, the flow velocity of the gas supplied to the peripheral edge portion of the wafer W on the inner side of the rotary table 12 and the peripheral edge portion of the wafer W on the outer side of the rotary table 12 is increased, whereby the amount of the DCS gas adsorbed on the wafer W is increased and the decrease in film thickness is suppressed.

Thereafter, the wafer W to which the DCS gas is absorbed sequentially passes through plasma formation regions P1 to P3 by the rotation of the rotary table 12. Active species such as radicals containing N (nitrogen) generated from the NH₃ gas are supplied onto the surface of each wafer W. As a result, a seed layer of a silicon nitride film is formed on the surface of the wafer W. Thereafter, by continuing to rotate the rotary table 12, the wafer W repeatedly and sequentially passes through the plasma formation regions P1 to P3 under the gas supply/exhaust unit 2. As a result, SiN is gradually laminated, and the film thickness of a SiN film reaches a predetermined film thickness.

According to the above-described embodiment, in the gas supply/exhaust unit 2 in which the gas is supplied so as to spread in a moving region of the wafer W in the radial direction of the rotary table 12 and in which the exhaust port 22 is provided so as to surround the gas discharge region 24, the gas discharge region 24 is partitioned into three or more sections along the radial direction of the rotary table 12. In the inner section 24A of the gas discharge region 24, the gas discharge holes 21 are provided in the region facing the inner peripheral edge of the passing region of the wafer W (the region of 15 mm away from the inner edge portion in the outer periphery direction of the rotary table 12). In the outer section 24C, the gas discharge holes 21 are provided in the outer peripheral edge of the passing region of the wafer W (the region 10 mm away from the outer edge portion in the center direction of the rotary table 12). Therefore, the supply amount of the gas to be supplied to the edge portion of the passing region of the wafer W can be increased. This makes it possible to suppress a decrease in film thickness at the peripheral edge of the wafer W.

The flow velocity of the DCS gas discharged from the outer section 24C is set to be higher than the flow velocity of the DCS gas discharged from the central section 24B, and the flow velocity of the DCS gas discharged from the inner section 24A is set to be higher than the flow velocity of the DCS gas discharged from the central section 24B. As a result, the DCS gas is supplied at a high flow velocity to the inner peripheral edge region and the outer peripheral edge region of the wafer W. Therefore, it is possible to suppress a decrease in film thickness at the inner peripheral edge and the outer peripheral edge of the wafer W. In this embodiment, the flow velocity of the DCS gas discharged from the outer section 24C is preferably two times or more as high as the flow velocity of the DCS gas discharged from the central section 24B. The flow velocity of the DCS gas discharged from the inner section 24A in this embodiment is preferably two times or more as high as the flow velocity of the DCS gas discharged from the central section 24B.

Furthermore, the average arrangement density of the gas discharge holes 21 in the outer section 24C is set to be smaller than the average arrangement density of the gas discharge holes 21 in the central section 24B. The average arrangement density of the gas discharge holes 21 in the inner section 24A is set to be smaller than the average arrangement density of the gas discharge holes 21 in the central section 24B. As a result, similar to the case where the flow velocity of the DCS gas discharged from each of the outer section 24C and the inner section 24A is set to be higher than the flow velocity of the DCS gas discharged from the central section 24B, the discharge amount of the DCS gas does not become too large in the region close to the inner peripheral edge of the wafer W and the region close to the outer peripheral edge of the wafer W, whereby an increase in film thickness is suppressed. In this embodiment, it is preferable that the arrangement density of the gas discharge holes 21 in the outer section 24C is set to be ⅕ or less of the arrangement density of the gas discharge holes 21 in the central section 24B. In addition, in this embodiment, it is preferable that the arrangement density of the gas discharge holes 21 in the inner section 24A is set to be ⅕ or less of the arrangement density of the gas discharge holes 21 in the central section 24B.

As described above, in the inner section 24A, the gas discharge holes 21 are provided in the inner edge region I facing the inner edge portion of the passing region of the wafer W (the region between the inner edge and the position 15 mm away from the inner edge toward the outer side of the rotary table 12). The gas discharge holes 21 are not provided in the region deviated from the inner edge region I. However, as long as the arrangement density DI₁ of the gas discharge holes 21 in the inner edge region I is larger than the arrangement density DI₂ of the gas discharge holes 21 in the region deviated (outward) from the inner edge region I (outward) in the inner section 24A, the gas discharge holes 21 may be provided in the region deviated from the inner edge region I. By providing the gas discharge holes 21 in this way, it is possible to prevent the film thickness from becoming excessively large in the region of the wafer W close to the inner periphery of the passing region of the wafer W. In this embodiment, it is preferable that the arrangement density DI₂ of the gas discharge holes 21 deviated from the edge region in the inner section 24A is ⅕ or less of the arrangement density DI₁ of the gas discharge holes 21 in the inner edge region I.

Furthermore, even in the outer section 24C, as long as the arrangement density DO₁ of the gas discharge holes 21 in the outer edge region O facing the outer edge of the passing region of the wafer W (the region between the outer edge and the position 10 mm away from the outer edge toward the center side of the rotary table 12) is larger than the arrangement density DO₂ of the gas discharge holes 21 in the region deviated from the outer edge region O (the region deviated inward), the gas discharge holes 21 may be provided in the region deviated from the outer edge region O. By providing the gas discharge holes 21 in this way, it is possible to prevent the film thickness from becoming excessively large in the region of the wafer W close to the outer periphery of the passing region of the wafer W. In this embodiment, in the outer section 24C, the arrangement density DO₂ of the gas discharge holes 21 in the region deviated from the outer edge region O is preferably ⅕ or less of the arrangement density DO₁ of the gas discharge holes 21 in the outer edge region O.

Further, when dividing the gas discharge region 24, a gap is formed at the boundary between the respective sections. Since the gap portion cannot discharge a gas, the film thickness in the region of the wafer W passing below the gap portion may be reduced. When the wafer passes under the gas discharge region 24 divided along the radial direction of the rotary table 12, if the direction of movement of the wafer W is similar to the direction of extension of the gap that divides the respective sections, the same position of the wafer W is repeatedly positioned below the gap as the wafer W moves under the gas discharge region 24. Thus, the film thickness is partially reduced.

In the embodiment described above, the gas discharge region 24 is formed such that the inner section 24A, the central section 24B and the outer section 24C are divided along the line L2 inclined by 10 degrees in the inner periphery direction of the rotary table 12 toward the downstream side of the rotation direction of the rotary table 12 with respect to the line L1 orthogonal to the diameter of the rotary table 12 passing through the end portion of the upstream side of the gas discharge region 24 in the rotation direction of the rotary table 12. Therefore, the direction of movement of the wafer W is separated from the direction of extension of the gap that divides the respective sections. Thus, it is possible to suppress a decrease in film thickness on a part of the wafer W. Furthermore, when dividing the gas discharge region 24 in the radial direction of the rotary table 12, the gas discharge region 24 may be divided into three or more sections.

### <Verification Test 1>

The following tests were conducted in order to verify the effects of the present disclosure. First, the number and distribution region of the gas discharge holes 21 in the inner section 24A and the film thickness distribution of the film formed on the wafer W, which depends on the flow rate of the gas supplied to the inner section 24A, were investigated.

### [Verification Test 1-1]

In the gas supply/exhaust unit 2 shown in FIGS. 3 and 4, the number of the gas discharge holes 21 in the outer section 24C was set to “256” and the gas discharge holes 21 were distributed over the entire lower surface of the outer section 24C. Further, the number of the gas discharge holes 21 in the inner section 24A was set to “124” and the gas discharge holes 21 were distributed on the entire lower surface of the inner section 24A. The number of the gas discharge holes 21 in the central section 24B was set to “632” and the gas discharge holes 21 were distributed over the entire lower surface of the central section 24B. The gas supply/exhaust unit 2 was used in the film forming apparatus described in the embodiment, and a SiN film was formed on the wafer W according to the film forming method described in the embodiment. In forming the SiN film, the gas supply amount in the gas supply/exhaust unit 2 was set so that the flow rate of the DCS gas supplied to the outer section 24C is 950 sccm and the flow rate of the DCS gas supplied to the central section 24B is 260 sccm. The flow rate of the DCS gas supplied to the inner section 24A was set to three kinds of flow rates, 50 sccm, 90 sccm and 150 sccm. A SiN film was formed on the wafer W according to the film forming method of the embodiment. For the respective flow rates in the inner section 24A, the film thickness distribution of the SiN film along the axis (Y axis) passing through the center of the wafer W and extending in the radial direction of the rotary table 12 was measured.

### [Verification Test 1-2]

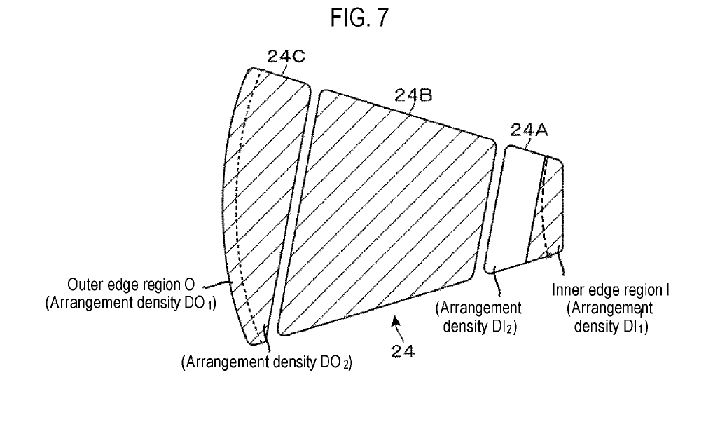

Verification test 1-2 is an example in which a SiN film was formed on the wafer W by setting the conditions as in verification test 1-1 except that the number of the gas discharge holes 21 in the inner section 24A was set to “35” and the gas discharge holes 21 were provided in the region of the bottom surface of the inner section 24A on the center side of the rotary table 12. The hatched area in FIG. 7 indicates the arrangement area of the gas discharge holes 21 in the gas discharge region 24 in verification test 1-2 as seen from the lower side. That is, in verification test 1-2, the arrangement density DI₁ of the gas discharge holes 21 in the inner edge region I is larger than the arrangement density DI₂ of the gas discharge holes 21 in the region deviated from the inner edge region I.

### [Verification Test 1-3]

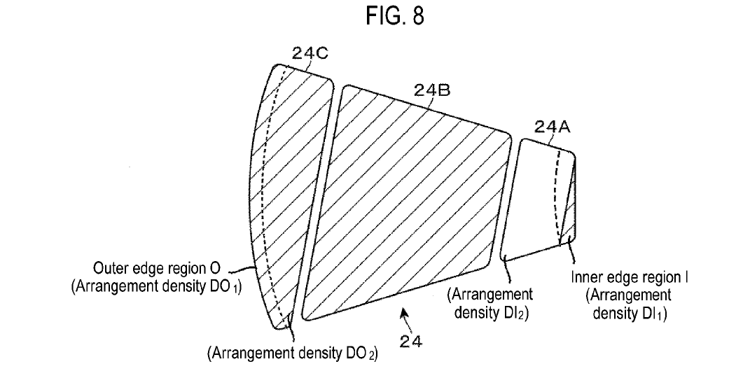

Verification test 1-3 is an example in which a SiN film was formed on the wafer W by setting the conditions as in verification test 1-1 except that the number of the gas discharge holes 21 in the inner section 24A was set to “9” and the gas discharge holes 21 were provided in the region of the bottom surface of the inner section 24A on the center side of the rotary table 12. The hatched area in FIG. 8 indicates the arrangement area of the gas discharge holes 21 in the gas discharge region 24 in verification test 1-3 as seen from the lower side. That is, in verification test 1-3, the gas discharge holes 21 are provided only in the inner edge region I, and the arrangement density DI₂ of the gas discharge holes 21 in the region deviated from the inner edge region I is set to 0.

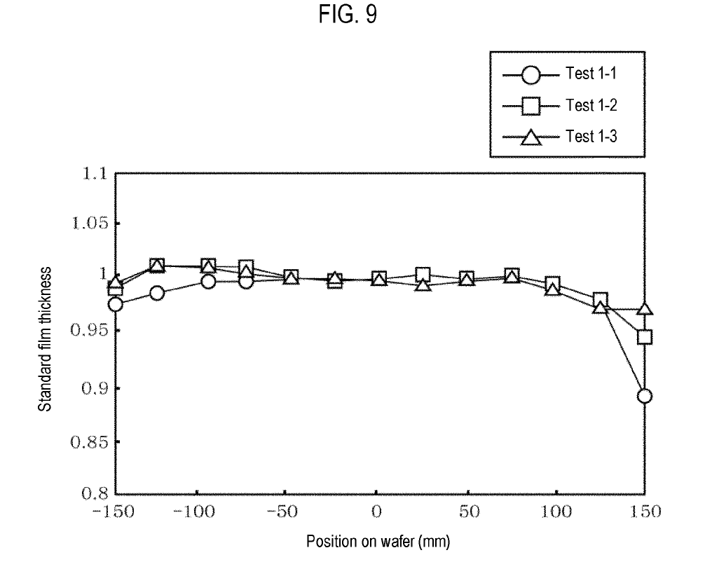

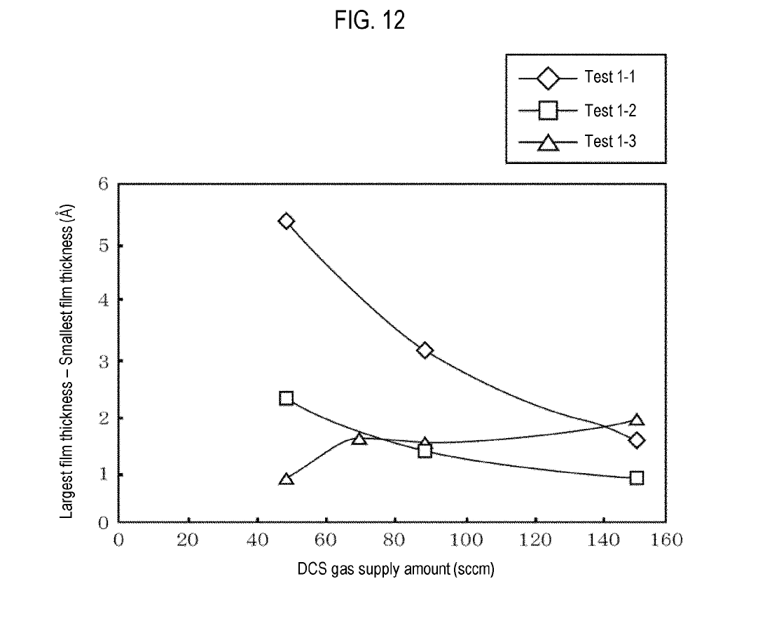

FIGS. 9 to 11 are characteristic diagrams showing the film thickness distribution on the Y axis of the SiN film on each wafer W when the flow rate of the DCS gas in the inner section 24A is set to 50 sccm, 90 sccm and 150 sccm, respectively. The horizontal axis in FIGS. 9 to 11 indicates the position on the wafer W along the radial direction of the rotary table 12. The central portion of the wafer W is indicated as an origin 0, the center side of the rotary table 12 in indicated as a positive value, and the outer periphery side of the rotary table 12 is indicated as a negative value. The vertical axis indicates a standard film thickness. The standard film thickness refers to a value indicating a film thickness at each point in terms of a percentage when the film thickness at the central portion of the wafer W is assumed to be 1. FIG. 12 shows a flow rate of the DCS gas supplied to the inner section 24A in verification tests 1-1 to 1-3 and a difference value between the film thickness in the largest film thickness region of the wafer W and the film thickness in the smallest film thickness region of the wafer W after a film is formed at the flow rate. In verification test 1-3, a difference value in the wafer W after the film formation when the flow rate of the DCS gas supplied to the inner section 24A is set to 70 sccm was also added.

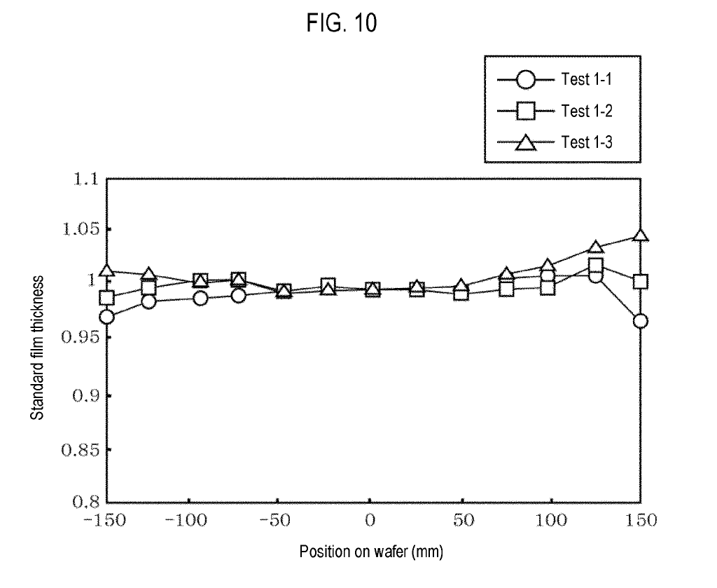

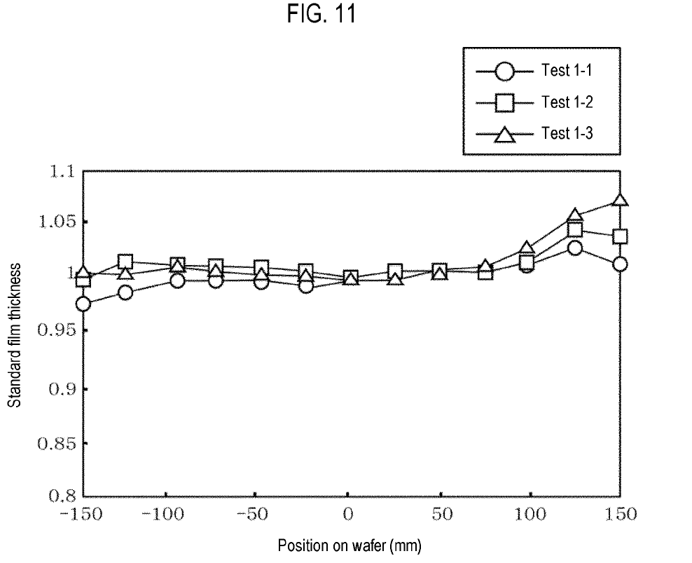

As shown in FIG. 9, in the wafer W of verification test 1-1, the film thickness in the peripheral edge portion closer to the center of the rotary table 12 tends to become small. It can be noted that, as the flow rate of the DCS gas supplied to the inner section 24A decreases, the film thickness in the peripheral edge closer to the center of the rotary table 12 becomes small. Further, as shown in FIGS. 10 and 11, it can be seen that the film thickness in the peripheral edge portion of the wafer W closer to the center of the rotary table 12 becomes smaller in the order of verification test 1-2 and verification test 1-3. As shown in FIGS. 9 to 11, the film thickness in the region of the wafer W shifted 100 mm to 150 mm from the center of the wafer W to the center side of the rotary table 12 largely varies depending on the flow rate of the DCS gas supplied to the inner section 24A. Furthermore, it can be seen that the film thickness at the point shifted 150 mm from the center of the wafer W to the center side of the rotary table 12 becomes larger in the order of verification test 1-1, verification test 1-2 and verification test 1-3. It can be understood that, when the flow rate of the DCS gas supplied to the inner section 24A is 90 sccm or more, the film thickness in the region of the wafer W shifted 100 mm to 150 mm from the center of the wafer W to the center side of the rotary table 12 is excessively increased. As shown in FIG. 12, it can be noted that, when the flow rate of the DCS gas supplied to the inner section 24A is set to 50 sccm in verification test 1-3, the in-plane uniformity of the film thickness is the best.

According to this result, it can be said that, by closing the gas discharge holes 21 except the gas discharge holes 21 that discharge the gas to the peripheral edge of the wafer W on the center side of the rotary table 12 in the inner section 24A, it is possible to increase film thickness at the peripheral edge of the wafer W on the center side of the rotary table 12. In addition, it can be said that, by providing the gas discharge holes 21 only on the center side of the rotary table 12 in the inner section 24A and setting the flow rate of the DCS gas supplied to the inner section 24A to 90 sccm or less, the uniformity of the film thickness becomes good in the region of the wafer W closer to the center of the rotary table 12.

### <Verification Test 2>

Next, the relationship between the number and distribution region of the gas discharge holes 21 in the outer section 24C and the film thickness distribution of the film formed on the wafer W, which depends on the flow rate of the gas supplied to the outer section 24C, was investigated.

### [Verification Test 2-1]

Verification test 2-1 is an example in which a process was performed in the same manner as in verification test 1-3 except that the flow rate of the DCS gas supplied to the inner section 24A was set to 70 sccm (the number of the gas discharge holes 21 in the inner section 24A: 9, the number of the gas discharge holes 21 in the central section 24B: 632, and the number of the gas discharge holes 21 in the outer section 24C: 256). In verification test 2-1, the flow rate of the DCS gas supplied to the outer section 24C was set to three kinds of flow rates, 950 sccm, 900 sccm and 840 sccm. A film was formed on the wafer W under each condition.

### [Verification Test 2-2]

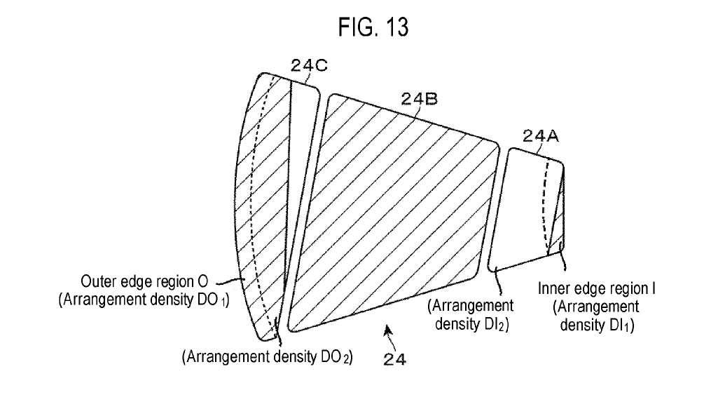

Verification test 2-2 is an example in which the conditions were set in the same manner as in verification test 2-1 except that the number of the gas discharge holes 21 in the outer section 24C was set to “204” and the gas discharge holes 21 were provided in the region of the outer section 24C closer to the outer periphery of the rotary table 12. The hatched area in FIG. 13 shows the arrangement area of the gas discharge holes 21 in the gas discharge region 24 in verification test 2-2 as seen from the lower side. That is, in verification test 2-2, the arrangement density DO₁ of the gas discharge holes 21 in the outer edge region O is larger than the arrangement density DO₂ in the region deviated from the outer edge region O. In verification test 2-2, the flow rate of the DCS gas supplied to the outer section 24C was set to two kinds of flow rates, 950 sccm and 840 sccm. A film was formed on the wafer W at each flow rate.

### [Verification Test 2-3]

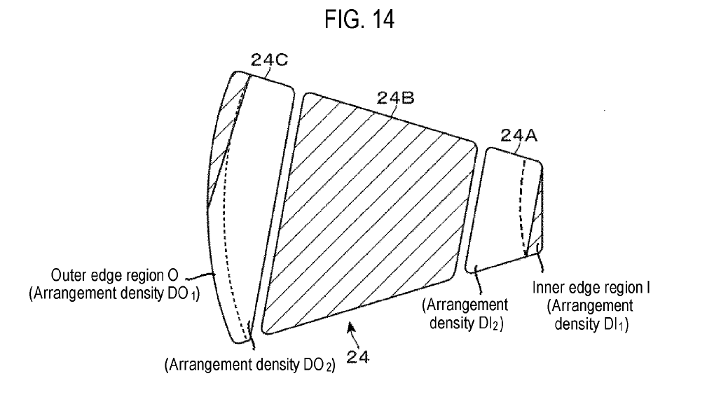

Verification test 2-3 is an example in which the conditions were set in the same manner as in verification test 2-1 except that the number of the gas discharge holes 21 in the outer section 24C is set to “21” and the gas discharge holes 21 were provided in the region of the bottom surface of the outer section 24C closer to the peripheral edge of the film forming apparatus. The hatched area in FIG. 14 indicates the arrangement area of the gas discharge holes 21 in the gas discharge region 24 in verification test 2-3 as seen from the lower side. That is, in verification test 2-3, the gas discharge holes 21 are provided only in the outer edge region O, and the arrangement density DO₂ of the gas discharge holes 21 in the region deviated from the outer edge region O is set to 0. In verification test 2-3, the flow rate of the DCS gas supplied to the outer section 24C was set to five kinds of flow rates, 950 sccm, 920 sccm, 900 sccm, 870 sccm and 840 sccm. A film was formed on the wafer W at each flow rate.

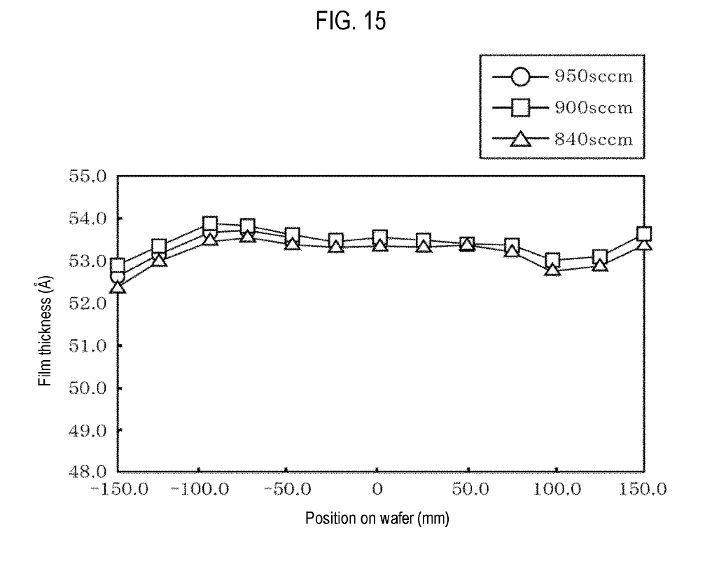

FIGS. 15 to 17 are characteristic diagrams showing the film thickness distribution on the Y axis of the SiN film formed on each wafer W in verification tests 2-1 to 2-3, respectively. The horizontal axis in FIGS. 15 to 17 indicates the position on the wafer W along the radial direction of the rotary table 12. The center of the wafer W is indicated as an origin 0, the center side of the rotary table 12 is indicated as a positive value, and the outer periphery side of the rotary table 12 is indicated as a negative value. In addition, the vertical axis indicates the film thickness (Å).

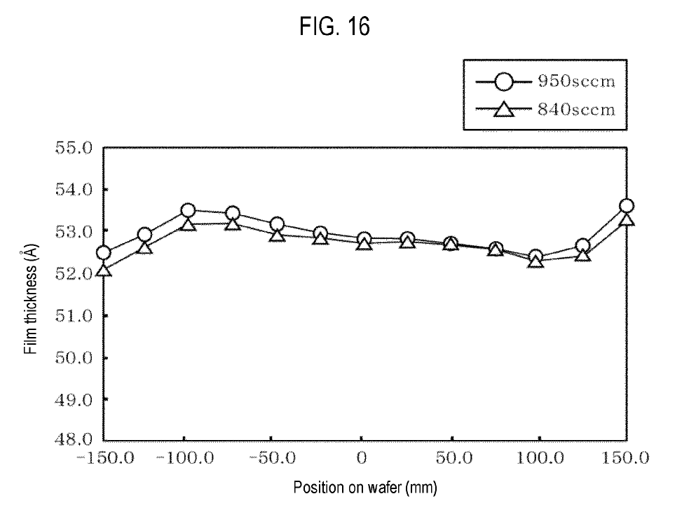

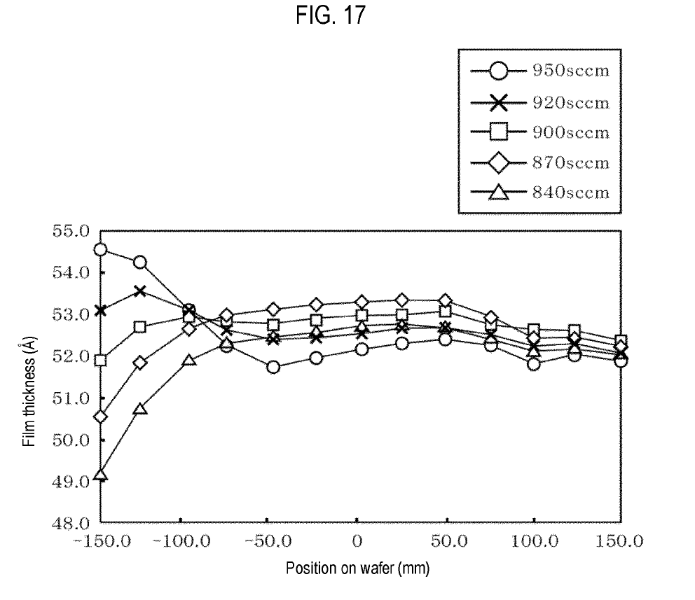

As shown in FIGS. 15 and 16, it can be noted that, in the wafers W of verification test 2-1 and verification test 2-2, the thin film thickness becomes small in the region shifted 100 to 150 mm from the center of the wafer W toward the outer periphery of the rotary table 12. It can also be understood that the film thickness distribution hardly changes even when the supply amount of the DCS gas is changed. As shown in FIG. 17, it can be seen that, in verification test 2-3, when the flow rate of the DCS gas supplied to the outer section 24C is set to 950 sccm, the film thickness in the region shifted 100 to 150 mm from the center of the wafer W toward the outer periphery of the rotary table 12 is larger than that of verification test 2-1 and verification test 2-2.

According to this result, it can be said that, by reducing the number of the gas discharge holes 21 in the outer section 24C and providing the gas discharge holes 21 at the position closer to the outer periphery of the rotary table 12, it is possible to increase film thickness at the peripheral edge of the wafer W closer to the outer periphery of the rotary table 12. Furthermore, when the supply amount of the DCS gas is set to 840 sccm, the film thickness in the region shifted 100 to 150 mm from the center of the wafer W toward the outer periphery of the rotary table 12 becomes smaller than that of verification test 2-1 and verification test 2-2. This is presumably because the gas discharge holes 21 are not present in the region of the outer section 24C on the center side of the rotary table 12 and, therefore, the flow rate of the gas flowing from the center side of the wafer W to the peripheral edge of the wafer W closer to the outer periphery of the rotary table 12 is small.

According to the present disclosure, in the first gas supply part which supplies a gas so as to spread in a substrate moving region in the radial direction of the rotary table and which includes the exhaust port provided so as to surround the gas discharge region, the gas discharge region is partitioned into three or more sections along the radial direction of the rotary table. In the inner section and the outer section respectively located on the center side and the outer periphery side of the rotary table in the gas discharge region, the arrangement density of the gas discharge holes in the region (edge region) opposed to the edge portion of the substrate passing region is set larger than the arrangement density of the gas discharge holes deviated from the edge region (including the case where the gas discharge holes are provided only in the edge region). Therefore, it is possible to increase the supply amount of the gas to be supplied to the edge portion of the substrate passing region. This makes it possible to suppress the decrease in the film thickness at the peripheral edge of the substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming apparatus for carrying out a film forming process on a substrate by performing a cycle of sequentially supplying a first processing gas and a second processing gas a plurality of times in a vacuum container, comprising:
a rotary table having one surface on which a substrate mounting region for mounting a substrate is formed, the rotary table configured to revolve the substrate mounting region in the vacuum container;
a first gas supply part including a gas discharge portion having a plurality of gas discharge holes of a first gas with a uniform hole diameter, an exhaust port surrounding the gas discharge portion, and a purge gas discharge port surrounding the gas discharge portion, which are formed on an opposing surface opposite the rotary table;
a second gas supply part configured to supply a second gas to a region spaced apart in a circumferential direction of the rotary table from the first gas supply part; and
an evacuation port configured to evacuate the inside of the vacuum container,
wherein the gas discharge portion includes three or more gas discharge regions divided in a radial direction of the rotary table and independently supplied with the first gas, and
when a center side of the rotary table is defined as an inner side and an outer periphery side of the rotary table is defined as an outer side,
in the gas discharge region positioned on a most outer side, an arrangement density DO₁ of the gas discharge holes in a region opposite an outer edge portion of a passing region of the substrate is set to be larger than an arrangement density DO₂ of the gas discharge holes in a region inwardly deviated from the region opposite the outer edge portion, and
in the gas discharge region positioned on a most inner side, an arrangement density DI₁ of the gas discharge holes in a region opposite an inner edge portion of the passing region of the substrate is set to be larger than an arrangement density DI₂ of the gas discharge holes in a region outwardly deviated from the region opposite the inner edge portion.

2. The apparatus of claim 1, wherein a flow velocity of the first gas discharged from the gas discharge region positioned on the most outer side is set to be higher than a flow velocity of the first gas discharged from a gas discharge region adjacent to the gas discharge region positioned on the most outer side, and
a flow velocity of the first gas discharged from the gas discharge region positioned on the most inner side is set to be higher than a flow velocity of the first gas discharged from a gas discharge region adjacent to the gas discharge region positioned on the most inner side.

3. The apparatus of claim 2, wherein the flow velocity of the first gas discharged from the gas discharge region positioned on the most outer side is twice or more as high as the flow velocity of the first gas discharged from the gas discharge region adjacent to the gas discharge region positioned on the most outer side, and
the flow velocity of the first gas discharged from the gas discharge region positioned on the most inner side is twice or more as high as the flow velocity of the first gas discharged from the gas discharge region adjacent to the gas discharge region positioned on the most inner side.

4. The apparatus of claim 1, wherein an arrangement density of the gas discharge holes in the gas discharge region positioned on the most outer side is smaller than an arrangement density of the gas discharge holes in a gas discharge region adjacent to the gas discharge region positioned on the most outer side, and
an arrangement density of the gas discharge holes in the gas discharge region positioned on the most inner side is smaller than an arrangement density of the gas discharge holes in a gas discharge region adjacent to the gas discharge region positioned on the most inner side.

5. The apparatus of claim 4, wherein the arrangement density of the gas discharge holes in the gas discharge region positioned on the most outer side is ⅕ or less of the arrangement density of the gas discharge holes in the gas discharge region adjacent to the gas discharge region positioned on the most outer side, and
the arrangement density of the gas discharge holes in the gas discharge region positioned on the most inner side is ⅕ or less of the arrangement density of the gas discharge holes in the gas discharge region adjacent to the gas discharge region positioned on the most inner side.

6. The apparatus of claim 1, wherein the arrangement density DO₂ is ⅕ or less of the arrangement density DO₁, and the arrangement density DI₂ is ⅕ or less of the arrangement density DI₁.
